(19) United States
(12) Patent Application Publication
(10) Pub. No.: US 2006/0263984 A1
(43) Pub. Date: Nov. 23, 2006

(54) Vertical nanotransistor, method for producing the same and memory assembly

(76) Inventors: Jie Chen, Berlin (DE); Martha Christina Lux-Steiner, Berlin (DE)

Correspondence Address: Law Offices of Karl Hormann, P O Box 381516, Cambridge, MA, 02238-1516, US

(21) Appl. No.: 10/568,230

(22) PCT Filed: Aug. 16, 2004
(86) PCT No.: PCT/DE04/01838

§ 371 Date: Feb. 11, 2006

(30) Foreign Application Priority Data
Aug. 21, 2003 (DE) 103 39 531.8

(51) Int. Cl. H01L 27/148; H01L 21/336

(52) U.S. Cl. 438/268; 257/242

(57) ABSTRACT

A vertical nano-transistor having a source region, a drain region, a gate region and a semiconductor channel region between the source region and the drain region, the gate region being constituted by a metal film into which the transistor is embedded in such a manner that the gate region and the semiconductor channel region form a coaxial structure, the source region, the semiconductor channel region and the drain region being disposed vertically, and the gate region being electrically insulated from the source region, the drain region and the semiconductor channel region. The invention also relates to a method of producing the inventive transistor and a memory assembly.

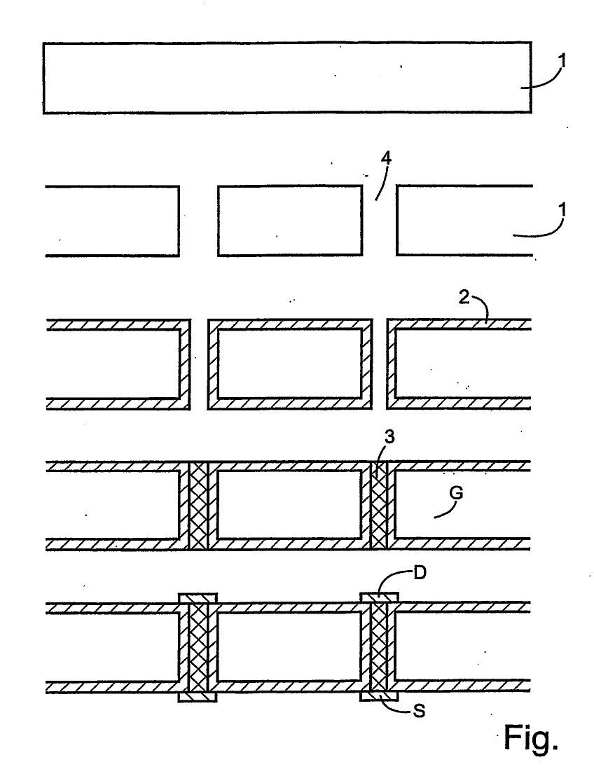

### BACKGROUND OF THE INVENTION

1. Field of the Invention

The invention relates to a vertical nano-transistor. A method of its fabrication and a memory assembly.

2. The Prior Art

German laid-open patent specification DE-OS 101 42 913 describes a transistor arrangement resisting mechanical stresses by bending, shearing or stretching in which semiconductor material is vertically introduced into micro-holes of a film composite consisting of plastic films with an intermediate metal layer. The semiconductor material is provided with metallic contacts at the upper and lower surfaces of the film composite. However, the application of a metal layer on a plastic film is no easy matter; moreover, the method of fabricating such a vertical transistor arrangement includes a plurality of individual method steps.

The fabrication of the vertical nano-transistor described by US 2002/0001905 is also complex and complicated, since initially a source region is applied to an expensive semiconductor substrate which is nor flexible onto which an insulating layer is applied. Holes in the nm-range are provided in the insulating layer (Al₂O₃ or Si), and vertically aligned carbon nano-tubes are inserted into these holes. The gate region is arranged above the insulating layer around the carbon nano-tubes and is filled with a non-conductive material up to the upper cover surface of the nano-tubes. Forming the gate region around the nano-tubes and maintaining identical diameters of these nano-tubes during filling has been proven to be very difficult. The result may be vertical transistor arrangements which because of the different diameters of the relevant nano-tubes are of different characteristics.

### OBJECT OF THE INVENTION

It is, therefore, an object of the invention to provide a vertical nano-transistor of good resistance against mechanical stresses and the fabrication of which is of lower complexity than what has hitherto been known in the prior art. A method of fabrication and a memory assembly are to be provided as well.

### SUMMARY OF THE INVENTION

In accordance with the invention, the object is accomplished by the provision of a vertical nano-transistor having a source region, a drain region, a gate region and a semiconductor channel region between the source region and the drain region, the gate region being formed by a metal film into which the transistor is embedded such that the gate region and the semiconductor channel region form a coaxial structure, the source region, the semiconductor channel region and the drain region being arranged in a vertical direction and the gate region being electrically insulated from the source region, the drain region and the semiconductor channel region.

In the system in accordance with the invention, the gate region is formed by an extremely thin metal film. The extremely difficult application of a metal layer onto a plastic film is avoided; also, unlike in the mentioned arrangement, the individual films need not be assembled into a composite film. The density of the holes formed in the metal film for providing the coaxial structures is very high.

Embodiments of the invention provide for cylindrically structuring the semiconductor channel region. The diameter of the semiconductor channel region amounts to from several ten to several hundred nanometers. The material of the semiconductor channel region is CuSCN or TiO₂ or PbS or ZnO or another compound semiconductor.

The thickness of the metal film forming the vertical gate region amounts to less than 100 μm, preferably 5 to 20 μm. Compared to plastic film, the height of the metal film is more uniform which, given the small thickness, ensures that the inserted holes do indeed penetrate through the film. Moreover, as a result of the very thin metal film the system according to the invention is highly resistant against mechanical stresses.

In another embodiment the thickness of the electrical insulation in the channel region amounts to several to several hundred nanometers. The thickness of the insulation layer at the upper and lower surfaces of the metal film amounts to several micrometers. The insulation layer may be applied by known processes of thin-film technology.

The material of the source and for the drain regions is Au or Ag or Cu or Ni or Al. The source and drain region may be structured as dots.

The system in accordance with the invention also includes a memory arrangement in which a plurality of vertical nano-transistors of the characteristics described in claim 1 are arranged adjacent each other on the metal film.

The method in accordance with the invention for fabricating vertical nano-transistors in accordance with claim 1 includes at least the following method steps: Forming holes in a thin metal film constituting the gate region of the transistor for providing the channel region, applying insulation material to the walls of the holes, applying insulation material on the upper and lower surface of the metal film, inserting semi-conductor material into the insulated holes for forming the semi-conductor channel region, applying contacts for forming the source and drain regions.

Embodiments of the method in accordance with the invention provide for the formation of the holes in the metal foil by focused ion beams or by laser beams.

The insulation material is applied by thin-film technology or by vacuum filtration of a polymeric solution onto the wall of the holes and onto the upper and lower surface of the metal film.

In other embodiments of the invention the semi-conductor material which may be CuSCN or TiO₂ or PbS or ZnO or another compound semi-conductor is introduced into the holes of the metal foil by electrochemical bath precipitation or chemical deposition or by the ILGAR process.

The fabrication method of the vertical nano-transistor arrangement in accordance with the invention is simple and adapts to the known thin-film technologies. As a result of the arrangement in accordance with the invention the fabrication method is no longer limited to predetermined temperatures.

### DESCRIPTION OF THE DRAWING

The novel features which are considered to be characteristic of the invention are set forth with particularity in the appended claims. The invention itself, however, in respect of its structure, construction and lay-out, as well as manufacturing techniques, together with other objects and advantages thereof, will be best understood from the following description when read with reference to the drawing.

The drawing depicts the fabrication steps of vertical nano-transistors in accordance with the invention which are embedded in a metal film.

### DETAILED DESCRIPTION OF THE PREFERRED EMBODIMENT

Initially holes 4 of a diameter of 200 nm are formed in an Al or Cu film of 30 μm thickness by laser irradiation. Thereafter, an insulation layer 2 of organic material, e.g. Al₂O₃, ZnS, SiO₂ or inorganic material e.g. polystyrene by vacuum filtration of a polymer solution, is applied to the wall of the holes 4. The thickness of this layer 2 is 50 nm. Thereafter, an insulation layer 2 of a thickness of several micrometers is also applied to the upper and lower surface of the metal film 1 by known thin-film technologies. Following this, the insulated holes 4 in the metal film 1 are filled with CuSCN. This concludes the formation of a semi-conductor channel region 3 of a diameter of 100 nm. As a final step, metallic contacts are applied as drain D and source S contacts.

What is claimed is:

1. (canceled)

2. The transistor of claim 23, in which the semiconductor channel region is structured cylindrically.

3. The transistor of claim 23, in which the thickness of the metal film forming the vertical gate region is less than 100 μm, preferably 5 to 20 μm.

4. The transistor of claim 23, in which the diameter of the semiconductor channel region is several ten to several hundred nanometers.

5. The transistor of claim 23, in which the thickness of the electrical insulation between the gate region and the semiconductor channel is several ten to several hundred nanometers.

6. The transistor of claim 23, in which the thickness of the insulation layer on the upper and lower surface of the metal film is several micrometers.

7. The transistor of claim 23, wherein the semiconductor channel comprises a material selected from the group consisting of CuSCN, TiO₂, PbS, ZnO and another compound semiconductor.

8. The transistor of claim 23, wherein the source and the drain regions comprise a material selected from the group consisting of Au, Ag, Cu, Ni and Al.

9. The transistor of claim 23, wherein the source and the drain region are structured as dots.

10. A memory arrangement, comprising:
a metal film;
a plurality of vertical nano-transistors according to claim 23 is arranged adjacent each other in the metal film.

11. A method of fabricating vertical nano-transistors according to claim 1, including at least the following method steps
forming holes in a thin metal film constituting the gate region of the transistor, for forming the channel region,
applying insulation material to the walls of the holes,
applying insulation material to the upper and lower surface of the metal film,
applying semiconductor material in the insulated holes for forming the semiconductor channel region,
applying contacts for forming the source and drain regions.

12. The method of claim 11, wherein the holes in the metal film are formed by focused ion beams.

13. The method of claim 11, wherein the holes in the metal film are formed by a laser beam.

14. The method of claim 11, wherein the insulation material is applied to the upper and lower surface of the metal film by thin-film technology.

15. The method of claim 11, wherein the insulation material is applied to the wall of the holes and to the upper and lower surface of the metal film by vacuum filtration of a polymer solution.

16. The method of claim 11, wherein the insulation material is applied to the wall of the holes and to the upper and lower surface of the metal foil by electrochemical deposition.

17. The method of claim 11, wherein the insulation material is applied to the wall of the holes and to the upper and lower surface of the metal foil by chemical deposition.

18. The method of claim 11, wherein the semiconductor channel region comprises a material selected from the group consisting of CuSCN, TiO₂, PbS, ZnO and another compound semiconductor.

19. The method of claim 11, wherein the semiconductor material is introduced into the insulated holes by electrochemical bath precipitation.

20. The method of claim 11, wherein the semiconductor material is introduced into the insulated holes by chemical deposition.

21. The method of claim 11, wherein the semiconductor material is introduced into the insulated holes by the ILGAR process.

22. The method of claim 11, wherein the source and drain regions comprise a material selected from the group consisting of Au, Ag, Cu, Ni and Al.

23. A vertical nano-transistor, comprising:
a source region;
a drain region;
a semiconductor channel region intermediate the source region and the drain region;
a gate region comprising a metal film, the transistor being embedded in the metal film such that the gate region and the semiconductor channel region form a coaxial structure and the source region, the semiconductor channel region and the drain region being vertically arranged; and
the gate region being electrically insulated from the source region, the drain region and the semiconductor channel region.
